(19) United States
(12) Patent Application Publication
(10) Pub. No.: US 2024/0057282 A1
(43) Pub. Date: Feb. 15, 2024

(54) SERVER

(71) Applicant: BEIJING TUSEN ZHITU TECHNOLOGY CO., LTD., Beijing (CN)

(72) Inventors: Zhihua MA, Beijing (CN); Haiquan LI, Beijing (CN); Xipeng LUAN, Beijing (CN)

(21) Appl. No.: 18/446,617

(22) Filed: Aug. 9, 2023

(30) Foreign Application Priority Data
Aug. 11, 2022 (CN) 202222115215.0

(51) Int. Cl. H05K 7/20

(52) U.S. Cl. CPC H05K 7/20154; H05K 7/20418

(57) ABSTRACT

Disclosed is a server. The server includes a housing, a support module, a heat-generating element set, and a heat dissipating unit. The housing defines an interior space, and the support module is positioned in the interior space. The heat-generating element set includes a central processing unit and a memory module. The heat dissipating unit includes a heat sink and a fan set. The heat sink and the support module divide the interior space into a first space and a second space. The heat-generating element set is located in the first space. A first surface of the heat sink contacts the heat-generating element set to dissipate heat from the heat-generating element set. The fan set is provided at a position of the housing corresponding to the second space to dissipate heat from the second space. This server can achieve efficient heat dissipation while ensuring the dustproof effect and structural stability.

### CROSS-REFERENCE TO RELATED APPLICATION

The present application claims priority to Chinese Patent Application No. 202222115215.0, titled “SERVER”, filed to China National Intellectual Property Administration on Aug. 11, 2022, the content of which is incorporated herein by reference in its entirety.

### TECHNICAL FIELD

The present disclosure relates to a server and, more particularly, to an in-vehicle server.

### BACKGROUND

Generally, an in-vehicle server for decision-making and control is provided on an autonomous vehicle for the need of automatic driving. In-vehicle servers face different challenges than general servers. A large amount of heat is generated during operation due to the technical complexity involved in automatically driving the vehicle, which imposes a high processing efficiency requirement on the in-vehicle server. Conventional heat dissipation means with a fan is easy to bring dust into the server while cooling, which affects the service life of the server. In addition, significant vibration is generated during the operation of the vehicle.

Existing in-vehicle servers and automatic driving in-vehicle servers have a main board-based architecture, with various boards and peripherals plugged thereto. Most of the accessories are assembled around the four walls of a server chassis and heat is removed from the boards in the chassis by a fan. Such a configuration may result in resonance oscillation and the like in the in-vehicle environment, and causes the in-vehicle server to be unstable in operation due to the accumulation of dust causing the breakdown of relatively precise hardware components of the server, such as a processor and a memory.

It is a technical problem to be solved urgently by those skilled in the art as to how to provide an appropriate in-vehicle server structure so as to achieve both the dustproof effect and structural stability while efficiently dissipating heat from the in-vehicle server.

### SUMMARY

The present disclosure provides a server capable of efficient heat dissipation while achieving both the dustproof effect and structural stability.

In an aspect of the present disclosure, a server is provided, including:
a housing forming an interior space;
a support module located in the interior space;
a heat-generating element set including a central processing unit and a memory module; and
a heat dissipating unit, including:
a heat sink, together with the support module, dividing the interior space into a first space and a second space, the heat-generating element set being located in the first space, the heat sink having a first surface facing the first space and a second surface facing the second space, and the second surface of the heat sink having a heat dissipating structure, in which the first surface of the heat sink contacts the heat-generating element set to dissipate heat from the heat-generating element set; and
a fan set provided at a position of the housing corresponding to the second space to dissipate heat from the second space.

Based on the above-mentioned disclosure, heat generated by the operation of the heat-generating element set can be conducted into the second space through the heat sink, while dust generated when the fan set dissipates heat from the second space does not enter the heat-generating element set in the first space. In addition, the support module provides a stable structure inside the server. Therefore, the server can achieve efficient heat dissipation while achieving both the dustproof effect and structural stability.

### BRIEF DESCRIPTION OF THE DRAWINGS

The accompanying drawings, which are incorporated in and constitute a part of this specification, illustrate embodiments and, together with the description, serve to explain exemplary embodiments of the embodiments. It is apparent that the drawings in the following description are only some rather than all embodiments of the present disclosure, and for a person skilled in the art, other drawings can be obtained according to these drawings without involving any inventive effort. Throughout the drawings, the same reference numerals indicate similar, but not necessarily identical, elements.

FIGS. 1 to 6 are structural diagrams of a server in a process of assembling according to an embodiment of the present disclosure (some elements are not shown);

FIG. 7 is an exploded view of a server according to an embodiment of the present disclosure.

### DETAILED DESCRIPTION

In order that those skilled in the art better understand the technical solution of the present disclosure, the technical solution of the embodiments of the present disclosure will be clearly and completely described below with reference to the accompanying drawings of the embodiments of the present disclosure. It is apparent that the described embodiments are only some rather than all embodiments of the present disclosure. Based on the embodiments of the present disclosure, all the other embodiments obtained by those of ordinary skill in the art without involving any inventive effort shall fall within the scope of the present disclosure.

In the present disclosure, the term “plurality” means two or more, unless otherwise specified. In the present disclosure, unless otherwise noted, the use of the terms “first”, “second”, and the like is intended to distinguish between similar objects and is not intended to limit their positional, temporal, or importance relationships. It is to be understood that the terms so used are interchangeable under appropriate circumstances such that the embodiments of the present disclosure described herein are capable of operation in other ways than those illustrated or otherwise described herein.

The server provided in the embodiments of the present disclosure can be applied to a vehicle with an automatic driving function or a vehicle with an auxiliary driving function, and can also be applied to a vehicle requiring manual driving. The present application does not strictly define the application scenario.

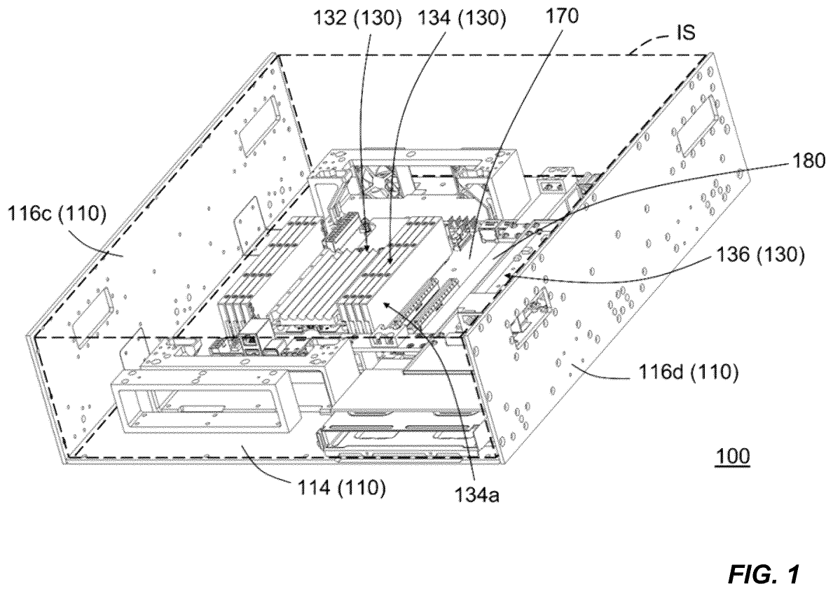

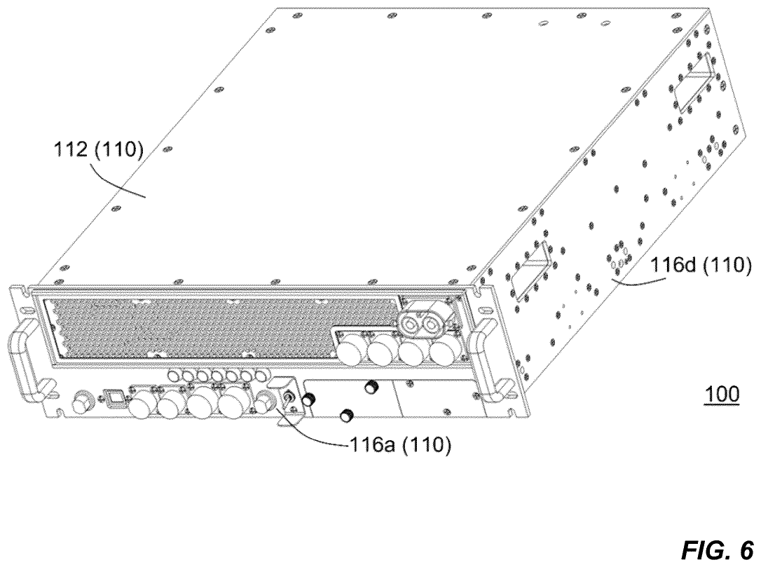

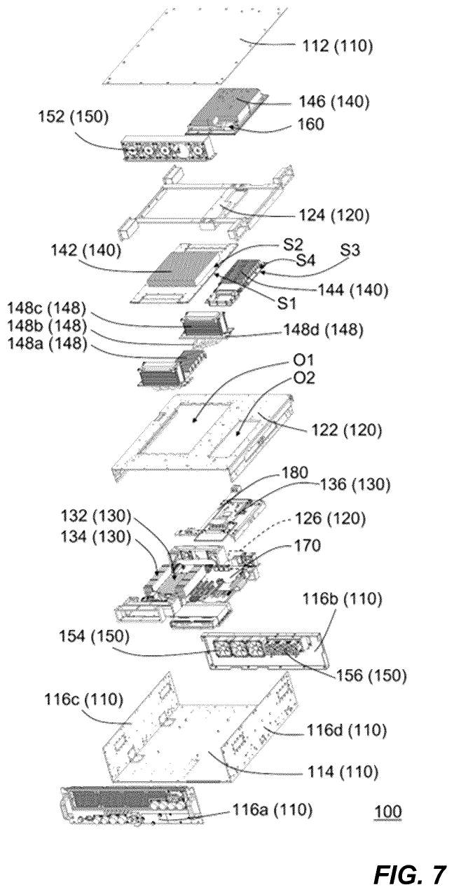

FIGS. 1 to 6 depict a process of mounting the server 100 in an embodiment of the present disclosure. FIG. 7 is an exploded view of the server 100. At least a portion of the illustrations of FIGS. 1 to 6 and FIG. 7 illustrate an interior structure of the server 100 and a relationship among various elements of the server 100.

Referring to FIGS. 1 and 5 to 7, in this embodiment, the server 100 includes a housing 110. The housing 110 includes, for example, an upper board 112, a lower board 114, and a plurality of side walls. These sidewalls include a first sidewall 116a, a second sidewall 116b, a third sidewall 116c, and a fourth sidewall 116d. The first sidewall 116a is opposite the second sidewall 116b, and the third sidewall 116c is opposite the fourth sidewall 116d. The first side wall 116a is, for example, a front panel of the server 100, and the second side wall 116b is, for example, a back panel opposite the front panel. Further, the third side wall 116c, the lower board 114, and the fourth side wall 116d form a U-shaped board structure. However, these side walls may also be provided with other structures or functions according to actual requirements, and the present disclosure is not limited thereto.

In this embodiment, the housing 110 forms an interior space IS. The interior space IS is, for example, a space surrounded by the upper board 112, the lower board 114, the first side wall 116a, the second side wall 116b, the third side wall 116c, and the fourth side wall 116d. The server 100 further includes a support module 120 in the interior space IS. The support module 120 includes a partition 122 having an opening to divide the interior space IS into a first space IS1 and a second space IS2. The first space IS1 is located below, i.e., on the side of the lower board 114, and the second space IS2 is located above, i.e., on the side of the upper board 112.

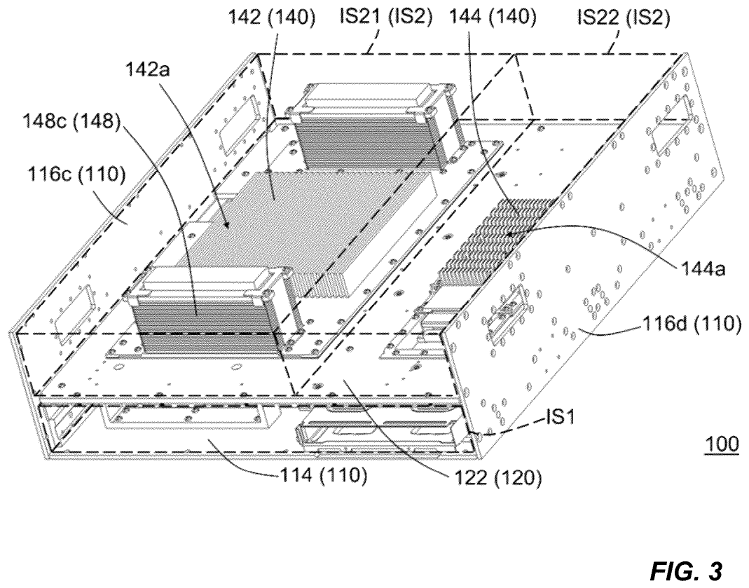

The server 100 further includes a heat-generating element set 130, a heat dissipating unit 140, a main board 170, and a daughterboard 180. The heat-generating element set 130 is in the first space IS1, and the heat-generating element set 130 includes a central processing unit (CPU) 132 and a memory module 134. The CPU 132 and the memory module 134 are mounted on the main board 170. The heat dissipating unit 140 includes a heat sink, i.e., a first heat sink 142. Referring to FIG. 3, the first heat sink 142 has a heat dissipating structure, i.e., a first heat dissipating structure 142a, to dissipate heat from the heat-generating element set 130 in the first space IS1.

In this embodiment, the heat sink (first heat sink 142) and the support module 120 divide the interior space IS into the first space IS1 and the second space IS2. Specifically, the opening of the partition 122 is a first opening O1 and accommodates the first heat sink 142. When the first heat sink 142 is mounted into the first opening O1, the lower board 114, the plurality of side walls, the partition 122, and the first heat sink 142 form the first space IS1. The first space IS1 is, for example, a closed space.

Referring to FIGS. 3 and 7, the first heat sink 142 has a first surface 51 facing the first space IS1 and a second surface S2 facing the second space IS2, and the second surface S2 of the first heat sink 142 has the heat dissipating structure (the first heat dissipating structure 142a of FIG. 3). Further, the first surface 51 of the first heat sink 142 contacts the heat-generating element set 130 to dissipate heat from the heat-generating element set 130. Specifically, the first surface 51 of the first heat sink 142 contacts the memory module 134 to dissipate heat from the memory module 134. In some embodiments, the first surface 51 of the first heat sink 142 may also contact the CPU 132 or other elements of the heat-generating element set to dissipate heat therefrom. In this embodiment, the memory module 134 includes at least one memory bank and at least one memory case 134a (shown in FIG. 1). The memory bank is covered by the memory case 134a, and the first surface 51 of the first heat sink 142 contacts the at least one memory case 134a to dissipate heat from the at least one memory case 134a. Specifically, this embodiment depicts eight memory cases 134a that can cover at least one memory bank to provide the heat dissipation and dustproof effect for the memory bank. The heat generated by the memory bank may be directed through the memory case 134a to the first heat sink 142 and into the second space IS2. The heat generated by the heat-generating elements of the heat-generating element set 130 may also be directed to the second space IS2 when the first heat sink 142 contacts or is close to the other heat-generating elements.

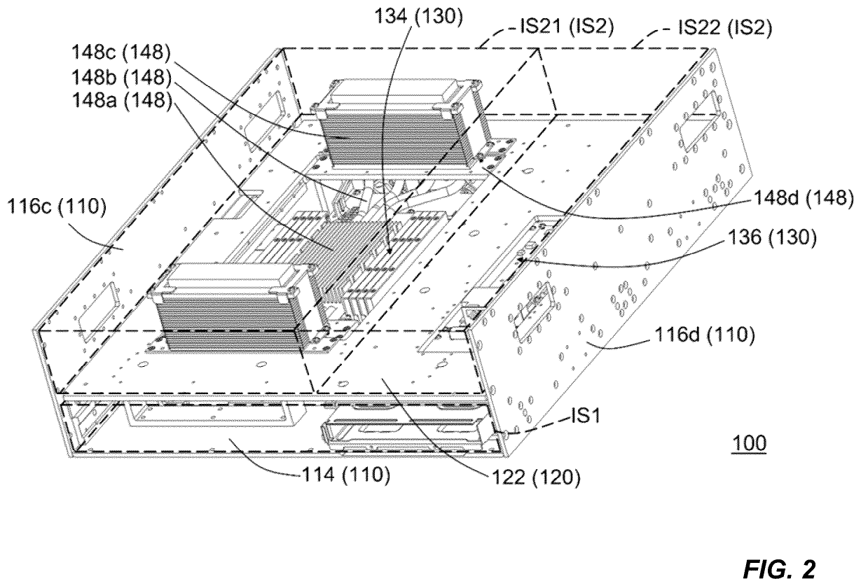

Referring to FIGS. 2 and 7, in this embodiment, the heat dissipating unit 140 further includes a processor heat dissipating unit 148. The processor heat dissipating unit 148 includes a heat conducting seat 148a, a heat conducting pipe 148b, and a heat dissipating module 148c. The heat dissipating module 148c is provided in the second space IS2, and the heat conducting seat 148a and the heat conducting pipe 148b are provided in the first space IS1. Specifically, the heat conducting seat 148a is mounted on the CPU 132, and the heat conducting pipe 148b connects the heat conducting seat 148a and the heat dissipating module 148c. The heat conducting seat 148a may include a base that contacts the CPU 132 and an upper cover. The number of the heat conducting pipes 148b may be one or more, and the base and the upper cover of the heat conducting seat 148a sandwich and fix the heat conducting pipe 148b so that the heat generated by the CPU 132 is conducted into the heat conducting pipe 148b. The heat conducting pipe 148b is filled with a heat conducting gel or a heat conducting liquid to conduct heat to the heat dissipating module 148c. The heat dissipating module 148c includes a plurality of heat dissipating fins to discharge heat to the second space IS2. In this embodiment, the number of the heat dissipating modules 148c is, for example, two, as shown in the drawings. Nonetheless, the number of the heat conducting pipes 148b and the number of the heat dissipating modules 148c may be appropriately configured according to actual requirements.

Referring to FIGS. 2 and 7, in this embodiment, the processor heat dissipating unit 148 further includes a heat dissipating module bottom board 148d, and the heat dissipating module bottom board 148d carries the heat dissipating module 148c. An opening (the first opening O1) of the partition 122 accommodates the first heat sink 142 and the heat dissipating module bottom board 148d. Specifically, in this embodiment, the number of the heat dissipating modules 148c is two, and the number of the heat dissipating module bottom boards 148d is also two. Each heat dissipating module bottom board 148d carries a heat dissipating module 148c. The first opening O1 accommodates both the first heat sink 142 and the two heat dissipating module bottom boards 148d. Specifically, the lower board 114, the plurality of side walls, the partition 122, the first heat sink 142, and the heat dissipating module bottom boards 148d form the first space IS1.

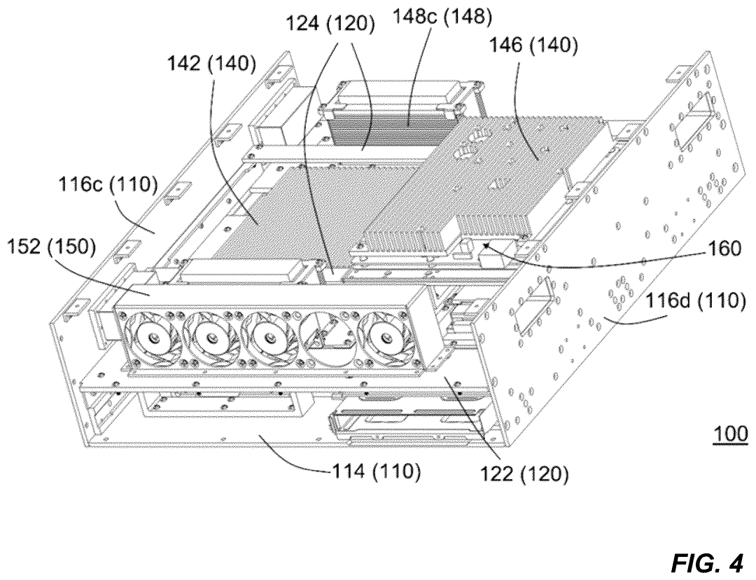

Referring to FIGS. 4, 5 and 7, the support module 120 further includes a first support 124 and a second support 126. The first support 124 is disposed between the partition 122 and the upper board 112, and the second support 126 is disposed between the partition 122 and the lower board 114. The heat-generating element set 130 further includes a network interface card 136 mounted on a daughterboard 180, and the second support 126 supports the daughterboard 180 above the main board 170. Referring to FIGS. 3 and 7, the heat dissipating unit 140 further includes a second heat sink 144, and the partition 122 further includes a second opening O2 for accommodating the second heat sink 144. When the second heat sink 144 is mounted into the second opening O2, the lower board 114, the plurality of side walls, the partition 122, the first heat sink 142, and the second heat sink 144 form the first space IS1. In some embodiments, the heat-generating element set 130 may also include a graphics processing unit (GPU) or a plurality of expansion cards mounted on the main board 170 or other boards in the first space IS1.

In this embodiment, the second heat sink 144 has a third surface S3 facing the first space IS1 and a fourth surface S4 facing the second space IS2. The fourth surface S4 of the second heat sink 144 has a second heat dissipating structure 144a, and the third surface S3 of the second heat sink 144 contacts the heat-generating element set 130 to dissipate heat from the heat-generating element set 130. Specifically, the third surface S3 of the second heat sink 144 contacts the network interface card 136 to dissipate heat from the network interface card 136. The second heat sink 144 may direct heat generated by the network interface card 136 to the second space IS2. In this embodiment, the second heat dissipating structure 144a is different from the first heat dissipating structure 142a, nonetheless, the second heat dissipating structure 144a may have the same structure as the first heat dissipating structure 142a according to actual requirements.

Referring to FIGS. 4, 5, and 7, in this embodiment, the server 100 further includes a power module 160 to provide a stable DC power supply for the server 100. The first support 124 supports the power module 160 such that the power module 160 is disposed between the first support 124 and the upper board 112. The heat dissipating unit 140 further includes a third heat sink 146 disposed on the power module 160. Specifically, the power module 160 and the third heat sink 146 are stacked above the second heat sink 144 cooling the network interface card 136, and the first heat sink 142 is disposed on the other side of the second space IS2. An upper space of the housing 110, that is, the second space IS2, includes a first portion IS21 and a second portion IS22 (see FIG. 3). A projection of the first portion IS21 on the upper board 112 does not overlap with a projection of the second portion IS22 on the upper board 112. The first heat sink 142 is within the first portion IS21 of the second space IS2, and the second heat sink 144 and the third heat sink 146 are within the second portion IS22 of the second space IS2.

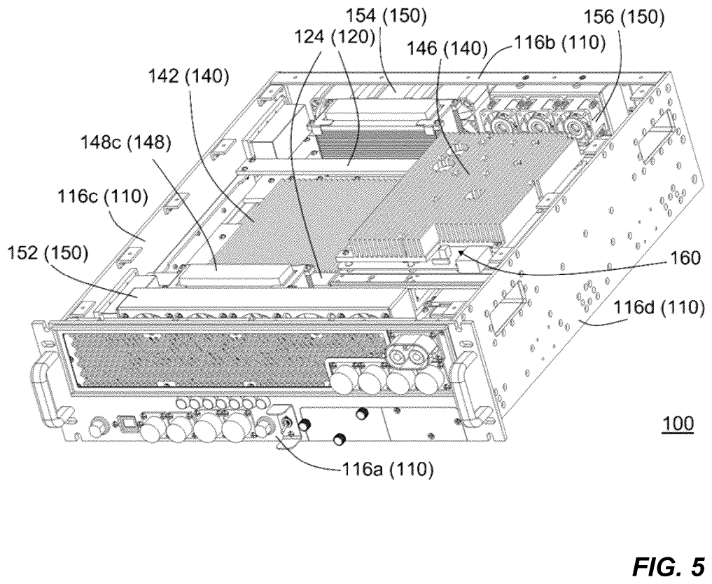

With continued reference to FIGS. 4, 5, and 7, the server 100 further includes a fan set 150 disposed at a position on the housing 110 corresponding to the second space IS2 so as to dissipate heat from the second space IS2. The fan set 150 includes a first fan set 152, a second fan set 154, and a third fan set 156. The first fan set 152 is disposed on a first sidewall 116a of the plurality of sidewalls, and the second fan set 154 and the third fan set 156 are disposed on a second sidewall 116b of the plurality of sidewalls. Referring to FIGS. 3 and 4, the first fan set 152 corresponds to the first portion IS21 and the second portion IS22 of the second space IS2. Referring to FIGS. 3 and 5, the second fan set 154 corresponds to the first portion IS21 of the second space IS2, and the third fan set 156 corresponds to the second portion IS22 of the second space IS2.

Specifically, the first fan set 152, the second fan set 154, and the third fan set 156 are disposed in the second space IS2 so as to provide an air flow in the second space IS2, thereby discharging heat of the second space IS2 out of the server 100. In this embodiment, the second fan set 154 is positioned adjacent the first heat sink 142 above the CPU 132 and the memory module 134 to dissipate heat from the first heat sink 142. The third fan set 156 is adjacent the second heat sink 144 above the network interface card 136 and the third heat sink 146 above the power module 160 to dissipate heat from the second heat sink 144 and the third heat sink 146. In this embodiment, since there is a distance between the second side wall 116b and the third heat sink 146, the third fan set 156 may be configured differently from the second fan set 154 in order to improve the heat dissipation efficiency of the third fan set 156. The third fan set 156 extends by a greater distance in the second space IS2 than a distance by which the second fan set 154 extends in the second space IS2. As such, the third fan set 156 is closer to the third heat sink 146 and closer to the second heat sink 144 to achieve better heat dissipation. However, the distance by which the third fan set 156 extends in the second space IS2 may also be set to be less than or equal to the distance by which the second fan set 154 extends in the second space IS2 according to actual requirements, and the present disclosure is not limited thereto. In addition, the number of fans of the first fan set 152, the second fan set 154, and the third fan set 156 may be configured according to actual needs, and more fans may be provided at other locations of the server 100 to achieve a better heat dissipation effect.

In this embodiment, the heat sink (e.g., the first heat sink 142 and the second heat sink 144) and the support module 120 divide the interior space IS into the first space IS1 and the second space IS2, and the heat-generating element set 130 such as the CPU 132 and the memory module 134 are located in the closed first space IS1. The heat sink contacts the heat-generating element set 130 to dissipate heat from the heat-generating element set 130. Accordingly, the heat generated by the operation of the heat-generating element set 130 can be conducted into the second space IS2 through the heat sink, and the heat can be discharged out of the server 100 through the fan set 150 cooling the second space IS2. Since the heat-generating element set 130 such as the CPU 132 and the memory module 134 are located in the closed first space IS1 and are blocked by the support module 120 such as the partition 122, dust generated when the fan set 150 dissipates heat from the second space IS2 does not enter the heat-generating element set 130 in the first space IS1. This enables the prevention of dust from entering the heat-generating element set 130 while efficient dissipation of heat for the server 100 in an in-vehicle operation environment, thereby achieving a more stable operation of the server 100.

In this embodiment, the partition 122 of the support module 120 provides stability to the overall structure of the server 100. The first support 124 supports the overall structure of the housing 122 of the server 100 and also supports the power module 160. The second support 126 supports the daughterboard 180 above the main board 170. Specifically, the main board 170 is also provided with a plurality of supporting mechanisms to support elements and boards above and reduce the possibility of cantilevering the elements. In this embodiment, the housing 110 and the support module 120 allow for various structural designs so that resonance of the server 100 in the in-vehicle vibration environment can be greatly reduced, whereby the server 100 in the in-vehicle operation environment can be more shock-resistant, and a more stable operation of the server 100 is ensured.

While exemplary embodiments or examples of the present disclosure have been described with reference to the accompanying drawings, it is to be understood that the above exemplary discussion is not intended to be exhaustive or to limit the present disclosure to the precise forms disclosed. Many modifications and variations are possible in light of the above teaching. Accordingly, the disclosed subject matter should not be limited to any single embodiment or example described herein, but rather should be construed in breadth and scope in accordance with the appended claims.

What is claimed is:

1. A server, comprising:
a housing forming an interior space;
a support module located in the interior space;
a heat-generating element set comprising a central processing unit and a memory module; and
a heat dissipating unit, comprising:
a heat sink, together with the support module, dividing the interior space into a first space and a second space, the heat-generating element set being located in the first space, the heat sink having a first surface facing the first space and a second surface facing the second space, and the second surface of the heat sink having a heat dissipating structure, in which the first surface of the heat sink contacts the heat-generating element set to dissipate heat from the heat-generating element set; and
a fan set provided at a position on the housing corresponding to the second space to dissipate heat from the second space.

2. The server according to claim 1, wherein the support module comprises a partition having an opening and the opening accommodates the heat sink; the housing comprises an upper board, a lower board, and a plurality of side walls, in which the lower board, the plurality of side walls, the partition, and the heat sink form the first space.

3. The server according to claim 2, wherein the heat sink of the heat dissipating unit is a first heat sink, and the heat dissipating structure of the first heat sink is a first heat dissipating structure; the heat dissipating unit further comprises a second heat sink, and the second heat sink has a third surface facing the first space and a fourth surface facing the second space, in which the fourth surface of the second heat sink has a second heat dissipating structure, and the third surface of the second heat sink contacts the heat-generating element set to dissipate heat from the heat-generating element set.

4. The server according to claim 3, wherein the opening of the partition is a first opening, and the partition further comprises a second opening to accommodate the second heat sink, in which the lower board, the plurality of sidewalls, the partition, the first heat sink, and the second heat sink form the first space.

5. The server according to claim 4, wherein the support module further comprises a first support disposed between the partition and the upper board, in which the server further comprises a power module, and the first support supports the power module so that the power module is disposed between the first support and the upper board.

6. The server according to claim 5, wherein the heat sink further comprises a third heat sink disposed on the power module, the second space comprises a first portion and a second portion, a projection of the first portion on the upper board does not overlap a projection of the second portion on the upper board, the first heat sink is located in the first portion of the second space, and the second heat sink and the third heat sink are located in the second portion of the second space.

7. The server according to claim 6, wherein the fan set comprises a first fan set disposed on a first side wall of the plurality of side walls, a second fan set disposed on a second side wall of the plurality of side walls, and a third fan set disposed on the second side wall of the plurality of side walls, in which the first side wall is opposite the second side wall.

8. The server according to claim 7, wherein the first fan set corresponds to the first portion and the second portion of the second space, the second fan set corresponds to the first portion of the second space, and the third fan set corresponds to the second portion of the second space.

9. The server according to claim 8, wherein the third fan set extends in the second space by a distance greater than a distance by which the second fan set extends in the second space.

10. The server according to claim 7, wherein the plurality of side walls further comprise a third side wall, and a fourth side wall opposite the third side wall, in which the third side wall, the lower board, and the fourth side wall form a U-shaped board structure, the first side wall being a front panel, and the second side wall being a back panel.

11. The server according to claim 3, wherein the heat-generating element set further comprises a network interface card, and the third surface of the second heat sink contacts the network interface card to dissipate heat from the network interface card.

12. The server according to claim 1, wherein the first surface of the heat sink contacts the memory module to dissipate heat from the memory module.

13. The server according to claim 1, wherein the heat sink further comprises a processor heat dissipating unit, the processor heat dissipating unit comprising a heat conducting seat, a heat conducting pipe, and a heat dissipating module, in which the heat dissipating module is disposed in the second space, the heat conducting seat and the heat conducting pipe are arranged in the first space, in which the heat conducting seat is mounted on the central processing unit, and the heat conducting pipe connects the heat conducting seat and the heat dissipating module.

14. The server according to claim 13, wherein the heat dissipating module comprises a plurality of heat dissipating fins, and the heat conducting pipe is filled with a heat conducting gel.

15. The server according to claim 13, wherein the processor heat dissipating unit further comprises a heat dissipating module bottom board for carrying the heat dissipating module; the support module comprises a partition having an opening, and the opening accommodates the heat sink and the heat dissipating module bottom board; the housing comprises the upper board, the lower board, and the plurality of side walls, in which the lower board, the plurality of side walls, the partition, the heat sink, and the heat dissipating module bottom board form the first space.

16. The server according to claim 1, further comprising a main board, in which the central processing unit and the memory module are mounted on the main board.

17. The server according to claim 16, further comprising a daughterboard, in which the heat-generating element set further comprises a network interface card mounted on the daughterboard, and the support module comprises a second support to support the daughterboard above the main board.

18. The server according to claim 1, wherein the memory module comprises at least one memory bank and at least one memory case, in which the memory bank is covered by the memory case, and the first surface of the heat sink contacts the at least one memory case to dissipate heat from the at least one memory case.
